(19) United States
(12) Patent Application Publication
(10) Pub. No.: US 2004/0123981 A1
(43) Pub. Date: Jul. 1, 2004

(54) Heat-dissicipating substrate

(76) Inventor: Frank Wang, Taipei (TW)

Correspondence Address: BIRCH STEWART KOLASCH & BIRCH, PO BOX 747, FALLS CHURCH, VA, 22040-0747, US

(21) Appl. No.: 10/331,987

(22) Filed: Dec. 31, 2002

(51) Int. Cl. F28F 7/00; H05K 7/20

(52) U.S. Cl. 165/185; 361/704; 165/80.3

(57) ABSTRACT

A heat-dissipating substrate to be tightly applied between a heat-dissipating device and a CPU. It consists of a baseboard and metal material. The baseboard contains several slots where the metal material fills in. When the CPU generates heat, the metal material, confined inside the slots and pressed by the tightly attached pressure between the heat-dissipating device and the CPU, melts and thoroughly fills the slots, and hence improves the snugness between the heat-dissipating device and the CPU, ultimately increasing heat-dissipating efficiency.

### BACKGROUND OF THE INVENTION

1. Field of Invention

The invention relates to a heat-dissipating substrate to be applied between a heat-dissipating device and a computer's Central Processing Unit (CPU) for increasing the snugness of the attachment between the heat-dissipating device and the CPU, thereby improving efficiency in dissipating heat.

2. Related Art

When an electronic device is being used, its elements usually generate too much heat such that it requires a heat-dissipating device to remove the heat out of the electronic device, in order to prevent the heat from accumulating in the elements and damage them. This is especially true when the CPU capacity is constantly increasing to meet higher demands. Using heat-dissipating device to resolve heat problem is an urgent problem.

The common practice for attaching a heat-dissipating device to a CPU is to use heat-dissipating glue, with which one side of the heat-dissipating device is glued to the surface of the CPU. Because of the increasing computing capacity of the CPU, the low heat-conductivity of the glue no longer meets the demands of the heat generated by the CPU. This un-met demand prompts the development of new substrates for dissipating heat.

The new heat-dissipating substrate is applied similarly to heat-dissipating glue; it is also to be applied between the heat-dissipating device 10 and the CPU 20 (refer to FIG. 3). The heat-dissipating substrate generally comprises of two structures: Referring to FIG. 1, the first structure uses copper as a baseboard 41, which is coated with a layer of Indium 41 because of its high heat-conductivity. While in use, certain regions of the CPU generate higher heat than others, which causes the heat-dissipating layer 42 to melt or even flow to other side due to the uneven intensive heat. The result is that, after several usages, the heat-dissipating layer 42 becomes thinner, or even disappears, and is no longer able to closely attach the heat-dissipating device 10 to the CPU 20. Therefore this type of heat-dissipating material is not suitable for repeated usage. Furthermore, since the heat-dissipating material is pressed by the tightly attached pressure between the coupled heat-dissipating device 10 and CPU 20, when the heat-dissipating layer 42 melts, the material tends to flow to where the pressure is lower, forming balls, or even fall onto the circuit board and damaging the circuitry. For this reason, the risk of using this material is increased.

Referring to FIG. 2, an alternative structure directly applies the heat-dissipating layer 42 made of Indium. However, because of the fact that certain regions of the CPU 20 exert higher temperatures than others, the heat-dissipating layer 42 attached to these regions becomes thinner or even disappears, and is no longer able to closely attach the heat-dissipating device 10 to the CPU 20. Therefore this type of heat-dissipating material is not suitable for repeated usage. Furthermore, since the heat-dissipating material is pressed by the tightly attached pressure between the coupling heat-dissipating device 10 and the CPU 20, when the heat-dissipating layer 42 melts, the material flows to where the pressure is lower, forming balls, or even falls onto the circuit board and damages the circuitry, thereby increasing the risk of using this material. For the reasons mentioned above, inventing a new heat-dissipating substrate to overcome these shortcomings is very important.

### SUMMARY OF THE INVENTION

The main objective of the invention is to provide a heat-dissipating substrate. By applying it between a heat-dissipating device and a CPU and causing it to melt when the CPU generates heat, the substrate can increase the snugness of the fit between the heat-dissipating device and the CPU, and therefore increase heat-dissipating efficiency.

The second objective of the invention is to provide a heat-dissipating substrate that can endure the pressure between the coupled heat-dissipating device and CPU. The substrate

The invention is a heat-dissipating substrate, to be tightly fitted between a heat-dissipating device and a CPU. It consists of a baseboard and metal material. The baseboard contains a plurality of slots where the metal material fills in. When the CPU generates heat, the metal material, confined inside the slots and pressed by the tightly attached pressure between the heat-dissipating device and the CPU, melts and thoroughly fills the slots, and hence improve the snugness between the heat-dissipating device and the CPU and increase heat-dissipating efficiency. Furthermore, because the metal material does not liquefy when it melts, it does not flow into un-intended areas. This property makes the metal material suitable for repeated usage with reduced risks.

Further scope of applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given herein. It should be understood, however, that the drawings are designed for the purpose of illustration only, and thus are not limitative of the invention.

FIG. 1 is a commonly known structure of heat-dissipating substrate;

FIG. 2 is another commonly known structure of heat-dissipating substrate;

FIG. 3 shows how heat-dissipating substrate is applied between the heat-dissipating device and the CPU;

FIG. 4 is the structure of invention of the heat-dissipating substrate; and

FIG. 5 is another example of applying the structure of the invention of the heat-dissipating substrate.

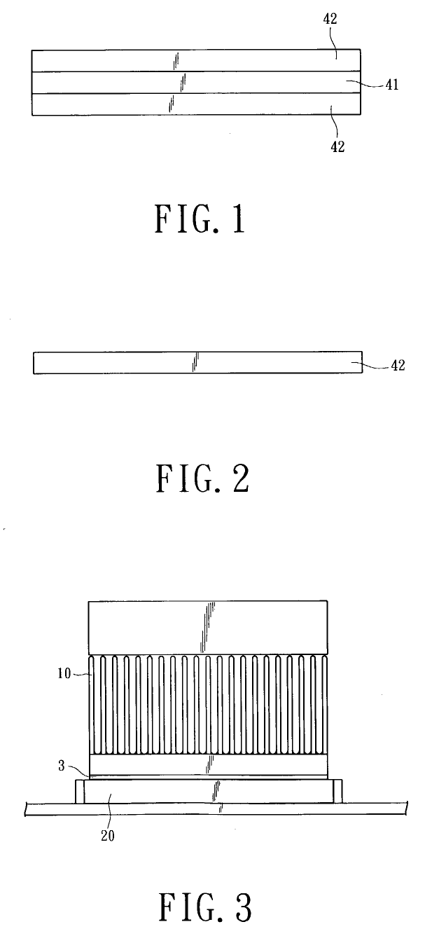

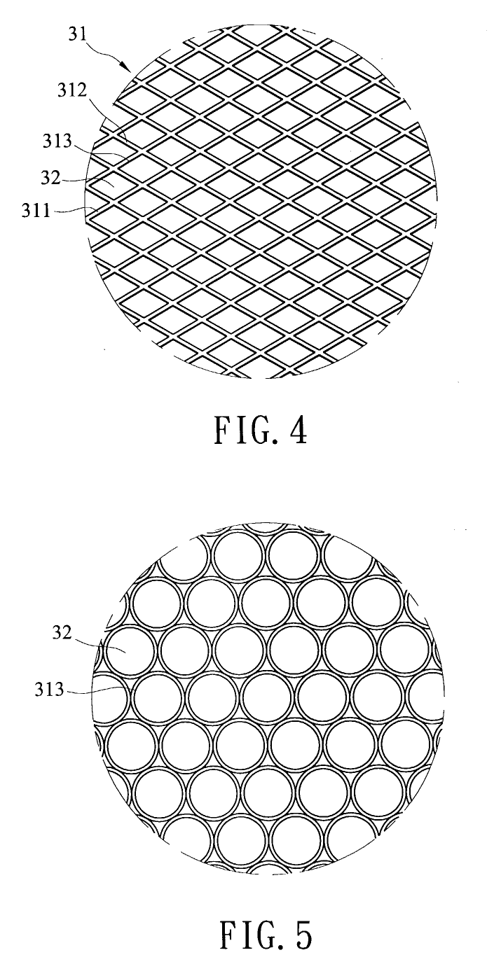

FIG. 4 is the structure of invention of the heat-dissipating substrate; and

FIG. 5 is another example of applying the structure of the invention of the heat-dissipating substrate.

### DETAILED DESCRIPTION OF THE INVENTION

Referring to FIG. 3 and according to the invention, the heat-dissipating substrate 3 is to be applied and tightly pressed by the tightly attached pressure between a heat-dissipating device 10 and a CPU 20, so that the contact surface area between the heat-dissipating device 10 and the CPU 20 increases when the CPU 20 generates heat.

Referring to FIG. 4, the heat-dissipating substrate 3 disclosed in the invention comprises a baseboard 31 and metal material 32. The baseboard 31 comprises several first metal strips 311 and several second metal strips 312. The material for the first metal strips 311 and second metal strips 312 is copper. A series of first metal strips 311 are arranged in parallel. A series of second metal strips 312 are also arranged in parallel, but series of second metal strips 312 are with an angle to the first series metal strips 311. Together these two series of parallel metal strips 311, 312 form a plurality of slots 313.

Metal material 32 is used to fill the slot 313 on the baseboard 31. This filling metal material 32 is Indium, which has high heat-conductivity.

When applying the invention, the first step is to place the heat-dissipating substrate 3 between the heat-dissipating device 10 and the CPU 20. The second step is to attach the heat-dissipating device 10 tightly to the CPU 20, so that the heat-dissipating substrate 3 is pressed by the tightly attached pressure between the coupled heat-dissipating device 10 and CPU 20. Because o f the tight attachment, the heat generated by the operating CPU 20 causes the high heat-conductive metal material 32 to melt, which in turn increases the contact area between the heat-dissipating device 10 and the CPU 20, resulting in even tighter attachment between the heat-dissipating device 10 and the CPU 20 and higher heat-removal efficiency. Since the filler metal material 32 is confined in slots 313, the metal material 32 will not overflow out of the slot 313 where it is supposed to fill. Therefore the metal material 32 will never leak between the heat-dissipating device 10 and the CPU 20, or fall onto the circuit board and cause damage.

Referring to FIG. 5, where the slots 313 are formed in circular shapes on the baseboard 31, the filler metal material 32 also fills the slots 313 and achieves the same results stated above. Regardless of the shape of the slots 313, the only requirement is that the metal filler material 32 be confined inside the slots when it melts. The size of the slots is also very small, so that the metal filler material 32 can be contained within.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heat-dissipating substrate, to be placed between a tightly attached heat-dissipation device and CPU, the heat-dissipating substrate comprises:
a baseboard, comprising a plurality of slots; and
a metal material, filling in the slots of the baseboard, when the baseboard pressed by the tightly attached pressure between the heat-dissipating device and the CPU and the CPU generating heat, the metal material confined within the slot melting in the slot only.

2. The heat-dissipating substrate of claim 1, wherein the baseboard comprises a plurality of first metal strips and a plurality of second metal strips, each of the first metal strips arranged in parallel, while the second metal strips arranged in parallel but at an angle to the first metal strips to construct slots.

3. The heat-dissipating substrate of claim 2, wherein the slots are in rectangular shapes.

4. The heat-dissipating substrate of claim 1, wherein the slots are in circular shapes.

5. The heat-dissipating substrate of claim 1, wherein the metal material has high thermal conductivity.

6. The heat-dissipating substrate of claim 5, wherein the metal material is Indium.

7. The heat-dissipating substrate of claim 1, wherein the first metal strips are copper.

8. The heat-dissipating substrate of claim 1, wherein the second metal trips are copper.
